(19) United States
(12) Patent Application Publication
(10) Pub. No.: US 2008/0035921 A1
(43) Pub. Date: Feb. 14, 2008

(54) METHOD AND CIRCUIT FOR DETECTING AND COMPENSATING FOR A DEGRADATION OF A SEMICONDUCTOR DEVICE

(76) Inventors: Christopher Gonzalez, Shelburne, VT (US); Vinod Ramadurai, South Burlington, VT (US); Norman Jay Rohrer, Underhill, VT (US)

Correspondence Address: SCHMEISER, OLSEN & WATTS, 22 CENTURY HILL DRIVE, SUITE 302, LATHAM, NY, 12110, US

(21) Appl. No.: 11/463,911

(22) Filed: Aug. 11, 2006

(51) Int. Cl. H01L 23/58

(52) U.S. Cl. 257/48

(57) ABSTRACT

A degradation detection method and circuit system for responding to degradation. The circuit system is located within a semiconductor device and comprises a process sensitive circuit, a measurement circuit, and a calculation circuit. The method comprises subjecting the semiconductor device to a first operating condition. A first value at a first time for a parameter of the process sensitive circuit is measured by the measurement circuit. The semiconductor device is operated to perform an intended function. A second value at a second time for the parameter of the circuit is measured by the measurement circuit. The second time is different from the first time. A first differential value between the first value and the second value is determined by the calculation circuit.

### BACKGROUND OF THE INVENTION

1. Technical Field

The present invention relates to a circuit for detecting and compensating for a degradation of a semiconductor device.

2. Related Art

Devices within an electrical structure typically degrade over time thereby causing the electrical structure to malfunction or operate inefficiently. Thus, there is a need for a structure and associated method for compensating for devices within an electrical structure that degrade over time.

### SUMMARY OF THE INVENTION

The present invention provides a degradation detection method, comprising:

providing, a semiconductor device comprising a monitor circuit system, said monitor circuit system comprising a process sensitive circuit, a measurement circuit, and a calculation circuit;

subjecting, said semiconductor device to a first operating condition;

first measuring, by said measurement circuit, a first value at a first time for a parameter of said process sensitive circuit;

operating after said first measuring, said semiconductor device such that said semiconductor device performs at least one intended function;

second measuring, by said measurement circuit, a second value at a second time for said parameter of said process sensitive circuit, said second time differing from said first time; and

determining, by said calculation circuit, a first differential value between said first value and said second value.

The present invention provides a semiconductor device, comprising:

a process sensitive circuit;

a measurement circuit, wherein said semiconductor device is adapted to be subjected to a first operating condition, wherein said measurement circuit is adapted to measure a first value for a parameter of said process sensitive circuit at a first time, wherein said semiconductor device is adapted to be operated such that said semiconductor device performs at least one intended function, wherein said measurement circuit is adapted to measure a second value for said parameter of said process sensitive at a second time, and wherein said second time differs from said first time; and

a calculation circuit adapted to determine a first differential value between said first value and said second value.

The present invention advantageously provides a structure and associated method for compensating for devices within an electrical structure that degrade over time.

### BRIEF DESCRIPTION OF DRAWINGS

FIG. 1 illustrates a block diagram of a semiconductor device comprising a degradation monitor circuit, in accordance with embodiments of the present invention.

FIG. 2 illustrates an internal schematic for the degradation monitor circuit of FIG. 1, in accordance with embodiments of the present invention.

FIG. 3 is a flowchart describing an algorithm for implementing the selection circuit 2 of FIGS. 1 and 2, in accordance with embodiments of the present invention.

### DETAILED DESCRIPTION OF THE INVENTION

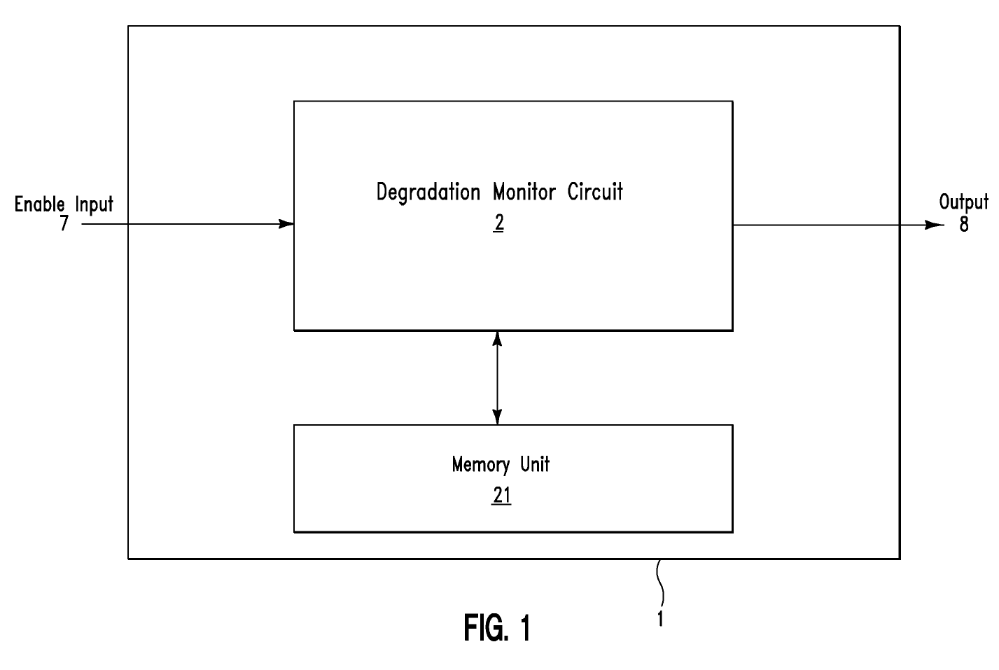

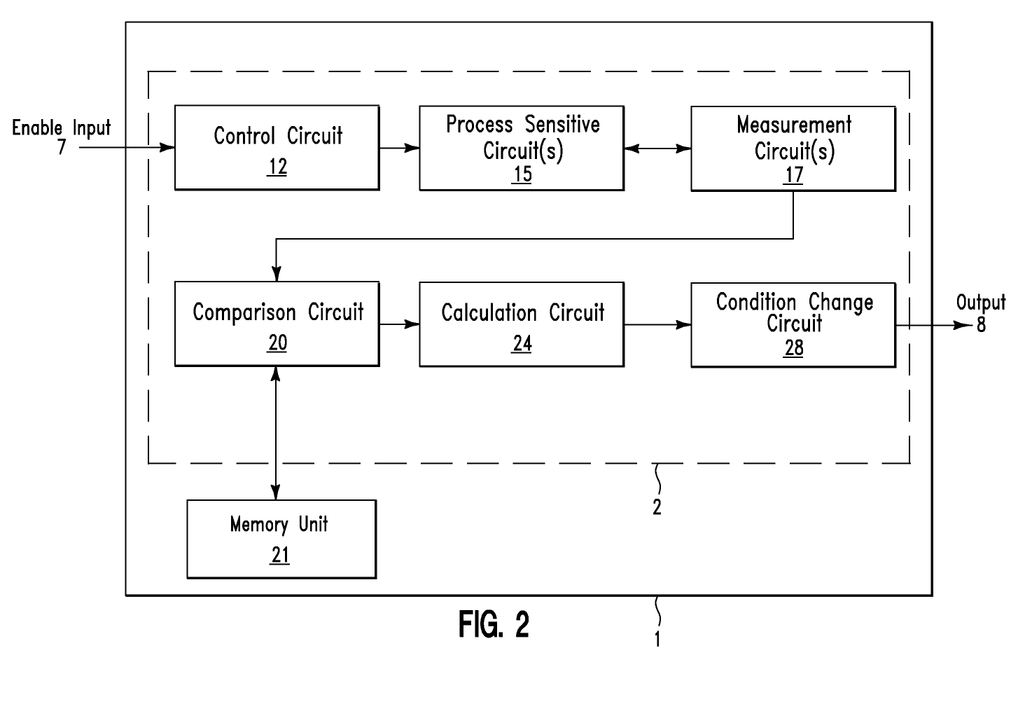

FIG. 1 illustrates a block diagram of a semiconductor device 1 comprising a degradation monitor circuit 2 and a memory unit 21, in accordance with embodiments of the present invention. The memory unit 21 may comprise a nonvolatile memory structure such as, inter alia, an e-fuse memory structure, a laser fuse memory structure, a random access memory (RAM) structure, etc. The semiconductor device 1 may comprise any type of semiconductor device including, inter alia, a semiconductor chip, a central processing unit (CPU), digital to analog converter, etc. The degradation monitor circuit 2 is a configurable circuit system comprising a plurality of circuits (e.g., see the internal schematic view in FIG. 2) and is used for detecting and accounting for semiconductor device degradation over time. Semiconductor device degradation is defined herein as the degrading of components (e.g., transistors, resistors, etc) and/or circuits within a semiconductor device caused by operation or usage of the semiconductor device. Once the degradation monitor circuit 2 has detected that the semiconductor device 1 has degraded, it may take several actions including, inter alia, sending a message to a user of the degradation monitor circuit 2 so that the user may adjust an operating condition(s) for the semiconductor device 1 in order to prevent semiconductor device 1 failure, automatically adjusting an operating condition(s) for the semiconductor device 1, etc. A message to the user of the degradation monitor circuit 2 may comprise any type of message including, inter alia, a visual message, an audible message, etc. Operating conditions for the semiconductor device 1 may include, inter alia, an operating or supply voltage for the semiconductor device 1, an operating or supply current for the semiconductor device 1, an operating temperature for the semiconductor device 1, a data flow to the semiconductor device 1, etc.

An enable signal (e.g., a logical 1) is applied to an enable input 7 for the degradation monitor circuit 2 in order to initialize a process for detecting semiconductor device 1 degradation over time. First, the semiconductor device 1 (including the degradation monitor circuit 2) is subjected to a first operating condition. For example, the first operating condition may comprise a first supply voltage (e.g., 1 volt) applied to the semiconductor device 1. A first value for a first parameter (e.g., resistance) of a circuit within degradation monitor circuit 2 (e.g., see process sensitive circuit(s) in FIG. 2) is measured at a first time and is stored in memory unit 21. The first parameter may comprise, inter alia, a delay for the circuit, a current for the circuit, a resistance for the circuit, a voltage for the circuit, etc. After the first value for the first parameter is measured, the semiconductor device 1 is operated under normal conditions. For example, if the semiconductor device is a CPU, then the CPU may be operated in a computer performing intended functions (e.g., performing calculations, performing control functions, running software, etc). After the semiconductor device 1 is operated under normal conditions for a specified time, a second value for the first parameter (e.g., resistance) of the circuit within degradation monitor circuit 2 (e.g., see process sensitive circuit(s) in FIG. 2) is measured at a second time (i.e., at the first operating condition) and stored in memory unit 21. A differential value between the first value and the second value is calculated by the degradation monitor circuit 2 and compared to a predetermined threshold value stored in memory unit 21. The predetermined threshold value may be determined by any means including, inter alia, experimentation, known values, etc.

If the differential value is greater than the predetermined threshold value then a notification is sent via the output 8 to indicate that the semiconductor device 1 has degraded and a system interrupt (i.e., to disable the semiconductor device 2) may be performed. The degradation monitor circuit 2 may suggest a change (i.e., change to the operating condition) for the semiconductor device 1 to ensure operability (i.e., to account for degradation). For example, the suggested change may comprise, inter alia, to lower an operating frequency, raise an operating voltage, change a workload, etc. The notification and suggested change may be sent to a user (e.g., a computer operator) of the semiconductor device 1 so that the user may manually change the first operating condition to a second operating condition (e.g., the first supply voltage of 1 volt is changed to a supply voltage of 1.1 volts). Alternatively, the suggested change may be sent to a system comprising the semiconductor device 1 (e.g., a computer comprising the semiconductor device 1) so that the system may automatically change the first operating condition to a second operating condition (e.g., the first supply voltage of 1 volt is changed to a supply voltage of 1.1 volts). For example, if the semiconductor device 1 is a CPU in a computer system, then the suggested change may be sent to the computer system so that the computer system may automatically make the suggested change to the operating condition. Upon making the suggested change from the first operating condition to the second operating condition (e.g., the first supply voltage of 1 volt is changed to a supply voltage of 1.1 volts) the aforementioned process may be performed again using the second operating condition to determine more semiconductor device 1 degradation. Additionally, the aforementioned process may be performed periodically.

If the differential value is less than the predetermined threshold value then a determination is made that the semiconductor device 1 has not degraded and the semiconductor device 1 is again operated at normal conditions at the first operating condition. The aforementioned measurement process may be performed again at a later time (e.g., periodically) to determine if the semiconductor device 1 has degraded at the later time.

Note that any operating condition for the semiconductor device 1 may be changed to perform the aforementioned process. For example, a temperature for the semiconductor device 1 may be changed by directing a heating source (e.g., a heater) or a cooling source (e.g., a fan, a heat sink, etc) at the semiconductor device 1 (i.e., subjecting the semiconductor device 1 to the operating condition).

FIG. 2 illustrates an internal schematic for the degradation monitor circuit 2 of FIG. 1, in accordance with embodiments of the present invention. The internal schematic for the degradation monitor circuit 2 in FIG. 2 represents an example configuration of components for the degradation monitor circuit 2. Note that any configuration of any components may be used. The degradation monitor circuit 2 comprises a control circuit 2, process sensitive circuit(s) 15, measurement circuit(s) 17, comparison circuit 20, calculation circuit 24, and condition change circuit 28. The control circuit 12 comprises digital logic circuitry (i.e., a collection of digital gates, such as, inter alia, NAND gates, NOR gates, latches, etc) and is used to control and enable the degradation monitor circuit 2. The control circuit 12 receives an enable signal in order to initialize a process for detecting semiconductor device 1 degradation over time. The process sensitive circuit(s) 15 comprises a plurality of test circuits used in the parameter measurement process as described with reference to FIG. 1. The process sensitive circuit(s) 15 may comprise a plurality of different test circuits each one producing a different type of output. For example, a first circuit may comprise be a ring oscillator circuit comprising inverters, a second circuit may comprise a ring oscillator circuit comprising latches, a third circuit may comprise a circuit that produces a current as an output, etc. The outputs of these circuits may comprise a voltage, a frequency, a current, any electrical measurement, etc.

After the semiconductor device 1 including the process sensitive circuit(s) 15 is subjected to a first operating condition. For example, the first operating condition may comprise a first supply voltage (e.g., 1 volt) applied to the semiconductor device 1. A first value for a first parameter (e.g., with respect to a ring oscillator circuit a first parameter may comprise a frequency) of one of the process sensitive circuit(s) 15 is measured at a first time and is stored in memory unit 21. The first parameter is measured by the measurement circuits 17. Additionally, the measurement circuits 17 convert all measured parameters to digital values. For example, if one of process sensitive circuit(s) 15 produces a voltage, then an analog to digital converter within measurement circuits 17 is used to convert an analog voltage to a digital number. Likewise, if one of process sensitive circuit(s) 15 produces a frequency (e.g., ring oscillator circuit), then the measurement circuits 17 would convert the analog frequency to a digital number. After the first value for a first parameter is measured and stored in memory unit 21, the semiconductor device 1 is operated under normal conditions. After the semiconductor device 1 is operated under normal conditions for a specified time, a second value for the first parameter of the process sensitive circuit(s) 15 is measured again at a second time (i.e., at the first operating condition) and stored in memory unit 21. The comparison circuit 20 compares the first value to the second value and the calculation circuit 24 calculates a differential value between the first value and the second value. The comparison circuit 20 may comprise comparator circuitry (e.g., digital comparators) to compare a given process sensitive circuit's current value (i.e., second value) to its initial value (i.e., first value). For example, at the beginning of its life a ring oscillator might have a measured frequency of 1 GHz but after running for a while it might now have a measured frequency of 900 MHz. The differential value between the first value and the second value is compared (i.e., by the comparison circuit 24) to a predetermined threshold value stored in memory unit 21.

If the differential value is greater than the predetermined threshold value then a notification may be sent via the output 8 to indicate that said semiconductor device 1 has degraded. The condition change circuit 28 may use a pre-calculated algorithm to produce a system interrupt (i.e., for the semiconductor device 2) and suggest a change (i.e., calculated by the calculation circuit 24) to the operating condition for the semiconductor device 2 to ensure operability and account for degradation. For example, condition change circuit 28 could ask a system operating the semiconductor device 2 to lower its operating frequency, raise its voltage, change its workload, etc. The notification and suggested change may be sent to a user of the semiconductor device 1 so that the user may manually change the first operating condition to a second operating condition (e.g., the first supply voltage of 1 volt is changed to a supply voltage of 1.1 volts). Alternatively, the suggested change may be sent to a system comprising the semiconductor device 1 so that the system may automatically change the first operating condition to a second operating condition (e.g., the first supply voltage of 2 volts is changed to a supply voltage of 1 volt). For example, if the semiconductor device 1 is a CPU in a computer system, then the suggested change may be sent to the computer system so that the computer system may automatically make the suggested change. Upon making the suggested change from the first operating condition to the second operating condition (e.g., the first supply voltage of 2 volts is changed to a supply voltage of 1 volt) the aforementioned process is performed again using the second operating condition to determine further degradation.

If the differential value is less than the predetermined threshold value then a determination is made that the semiconductor device 1 has not degraded and the semiconductor device 1 is again operated at normal conditions.

The aforementioned measurement process may be performed again at a later time (e.g., periodically) to determine if the semiconductor device 1 has degraded at the later time. Additionally the aforementioned process may be performed using a plurality of circuit within the process sensitive circuits 15 as illustrated by the following example of implementation for the degradation monitor circuit 2 of FIGS. 1 and 2.

In the example a process degradation monitor circuit 2 comprises two circuits: a ring oscillator circuit comprising regular threshold voltage (RVT) devices and a ring oscillator circuit comprising high threshold voltage devices (HVT) as the process sensitive circuits 15. After the semiconductor device 1 is manufactured it is tested. During the test the control circuit 12 will test (either in parallel or sequentially) the RVT circuit and the HVT circuit. In the example, the RVT circuit and the HVT circuit are tested sequentially. The control circuit 12 will enable the RVT circuit and the measurement circuit 17 will measure a frequency of its output. The measurement circuit 17 measures a value of 1 GHz for a parameter (i.e., frequency) of the RVT circuit. The value (i.e., 1 GHz) is stored in the memory unit 21. Next, the control circuit 12 enables the HVT circuit and the measurement circuit 17 measures a value of 0.5 GHz. This value is also stored in the memory unit 21. These two values (1 GHz and 0.5 GHz) are stored as time T0 valued measurements for each circuit.

The semiconductor device 1 is now put into operation and periodically (e.g., during boot-up, every hour, every day, etc), the process degradation monitor circuit 2 interrogates the RVT circuit and the HVT circuit. Every time the control circuit 12 enables the RVT circuit and the HVT circuit, the measurement circuit 17 measures output values, the comparison circuit 20 compares values, the calculation circuit 24 calculates a delta frequency from time T0, and the condition change circuit 28 provides semiconductor device 1 recommendations. For example, the process degradation monitor circuit 2 re-measures the HVT circuit and the RVT circuit and compares the re-measure values to the T0 values. Currently, the HVT circuit measures 0.5 GHz and the RVT circuit measures 0.9 GHz. The process degradation monitor circuit 2 compares the current HVT circuit value of 0.5 GHz to the T0 value of 0.5 GHz and because there is no change there are no system changes recommended. The RVT circuit T0 value of 1.0 GHz is compared to the 0.9 MHz current value. Based on a delta of 10% between the T0 value and the current value, the condition change circuit 28 will send signals to the system requesting either the system to slow down or the operating voltage to be raised, etc.

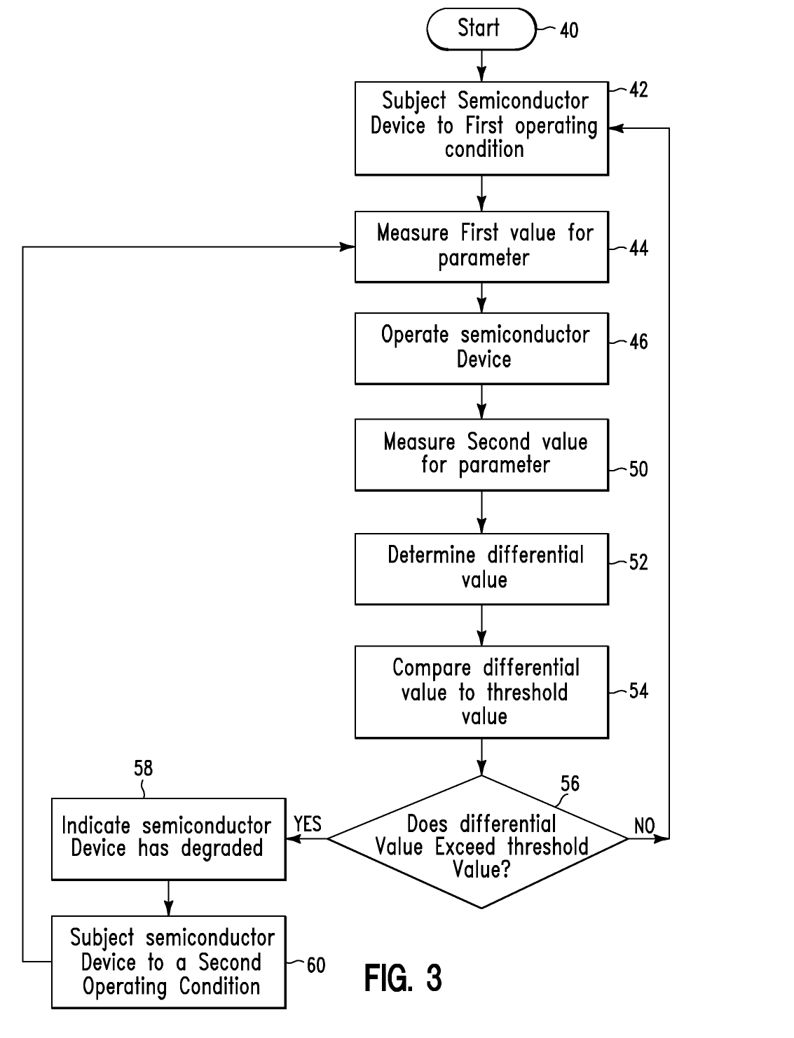

FIG. 3 is a flowchart describing an algorithm for implementing the selection circuit 2 of FIGS. 1 and 2, in accordance with embodiments of the present invention.

In step 40, the process is initiated. In step 42, the semiconductor device 1 is subjected to a first operating condition. In step 44, a first value for a parameter of a first circuit within the process sensitive circuits 15 is measured. In step 46, the semiconductor device 1 is operated at normal conditions. In step 50, a second value for the parameter of the first circuit within the process sensitive circuits 15 is measured. In step 52, a differential value between the first value and the second value is determined. In step 54, the differential value is compared to a predetermined threshold value. In step 56, it is determined if the differential value exceeds the predetermined threshold value.

If in step 56, it is determined that the differential value exceeds the predetermined threshold value then in step 58, the condition change circuit 28 indicates that the semiconductor device 1 has degraded. In step 60, the semiconductor device is subjected to a second operating condition and step 44 is repeated.

If in step 56, it is determined that the differential value does not exceed the predetermined threshold value then step 42 is repeated.

While embodiments of the present invention have been described herein for purposes of illustration, many modifications and changes will become apparent to those skilled in the art. Accordingly, the appended claims are intended to encompass all such modifications and changes as fall within the true spirit and scope of this invention.

What is claimed is:

1. A degradation detection method, comprising:
providing, a semiconductor device comprising a monitor circuit system, said monitor circuit system comprising a process sensitive circuit, a measurement circuit, and a calculation circuit;
subjecting, said semiconductor device to a first operating condition;
first measuring, by said measurement circuit, a first value at a first time for a parameter of said process sensitive circuit;
operating after said first measuring, said semiconductor device such that said semiconductor device performs at least one intended function;
second measuring, by said measurement circuit, a second value at a second time for said parameter of said process sensitive circuit, said second time differing from said first time; and
determining, by said calculation circuit, a first differential value between said first value and said second value.

2. The method of claim 1, wherein second measuring is performed during said operating.

3. The method of claim 1, wherein said monitor circuit system further comprises a comparison circuit, and wherein said method further comprises:
comparing, by said comparison circuit, a first specified threshold value to said first differential value to determine if said first differential value exceeds said first specified threshold value.

4. The method of claim 3, wherein said monitor circuit system further comprises a condition change circuit, wherein said comparing determines that said first differential value exceeds said first specified threshold value, and wherein said method further comprises:
enabling, by said condition change circuit, a second operating condition; and
subjecting, said semiconductor device to said second operating condition, said second operating condition differing from said first operating condition.

5. The method of claim 4, wherein said subjecting said semiconductor device to said second operating condition is performed automatically by an apparatus comprising said semiconductor device.

6. The method of claim 4, further comprising:
periodically measuring, by said measurement circuit, a plurality of values for said parameter; and
determining, by said calculation circuit, differential values between said first value and each of said plurality of values.

7. The method of claim 6, further comprising:
comparing, by said comparison circuit, a second specified threshold value to each of said differential values to determine if any of said differential values exceed said second specified threshold value, said second specified threshold value less than said first specified threshold value.

8. The method of claim 3, wherein said monitor circuit system further comprises a condition change circuit, wherein said comparing determines that said first differential value exceeds said first threshold value, and wherein said method further comprises:
transmitting, by said condition change circuit to a user of an apparatus comprising said semiconductor device, a notification message that said first operating condition of said semiconductor device requires a change; and
subjecting, by said user, said semiconductor device to said second operating condition, said second operating condition differing from said first operating condition.

9. The method of claim 8, wherein said notification message comprises a message selected from the group consisting of a visual message and an audible message.

10. The method of claim 3, wherein said semiconductor device further comprises a memory structure, and wherein said method further comprises:
storing, said first value, said second value, said first differential value, and said first threshold value within said memory structure.

11. A semiconductor device, comprising:
a process sensitive circuit;
a measurement circuit, wherein said semiconductor device is adapted to be subjected to a first operating condition, wherein said measurement circuit is adapted to measure a first value for a parameter of said process sensitive circuit at a first time, wherein said semiconductor device is adapted to be operated such that said semiconductor device performs at least one intended function, wherein said measurement circuit is adapted to measure a second value for said parameter of said process sensitive at a second time, and wherein said second time differs from said first time; and
a calculation circuit adapted to determine a first differential value between said first value and said second value.

12. The semiconductor device of claim 11, further comprising:
a comparison circuit adapted to compare a first threshold value to said first differential value to determine if said first differential value exceeds said threshold value.

13. The semiconductor device of claim 12, further comprising:
a condition change circuit adapted to enable a second operating condition if said first differential value exceeds said first specified threshold value, wherein said semiconductor device is adapted to be subjected to said second operating condition, and wherein said first operating condition is different from said second operating condition.

14. The semiconductor device of claim 13, wherein said semiconductor device is comprised by an apparatus, and wherein said apparatus is adapted to automatically subject said semiconductor device to said second operating condition.

15. The semiconductor device of claim 13, wherein said by said measurement circuit is adapted to periodically measure a plurality of values for said parameter, and wherein said calculation circuit is adapted to determine differential values between said first value and each of said plurality of values.

16. The semiconductor device of claim 12, further comprising a condition change circuit adapted to transmit to a user of an apparatus comprising said semiconductor device, a notification message that said first operating condition of said semiconductor device requires a change if said first differential value exceeds said first specified threshold value.

17. The semiconductor device of claim 16, wherein said notification message comprises a message selected from the group consisting of a visual message and an audible message.

18. The semiconductor device of claim 12, further comprising:
a memory structure adapted to store, said first value, said second value, said first differential value, and said threshold value.

19. The semiconductor device of claim 18, wherein said memory structure comprises a nonvolatile memory structure.

20. The semiconductor device of claim 19, wherein said nonvolatile memory structure comprises a structure selected from the group consisting of an e-fuse structure, a laser fuse structure, and a RAM structure.
